(19) United States
(12) Patent Application Publication
(10) Pub. No.: US 2008/0117984 A1
(43) Pub. Date: May 22, 2008

(54) Pre-Clock/Data Recovery Multiplexing of Input Signals in a HDMI Video Receiver

(75) Inventors: Jianbin Hao, San Jose, CA (US); Ning Zhu, San Jose, CA (US); Yanjing Ke, Union City, CA (US)

Correspondence Address: BLAKELY SOKOLOFF TAYLOR & ZAFMAN, 1279 OAKMEAD PARKWAY, SUNNYVALE, CA, 94085-4040, US

(73) Assignee: ANALOGIX SEMICONDUCTOR, INC., Santa Clara, CA (US)

(21) Appl. No.: 11/869,592

(22) Filed: Oct. 9, 2007

Related U.S. Application Data
(60) Provisional application No. 60/859,639, filed on Nov. 16, 2006.

(51) Int. Cl. H03K 5/159

(52) U.S. Cl. 375/240.26

(57) ABSTRACT

High Definition Multimedia Interface (HDMI) receivers use digital multiplexer at the input stage after equalization, clock and data recovery for each channel of each port. Described herein is the use of an analog multiplexer for HDMI receiver. The purpose of the analog multiplexer is to reduce the die size and power consumption by selecting the input signal from one port out of a set of input ports, right after the equalization and hence use only one block of clock and data recovery (CDR) circuits for the receiver. This sharing of one block of CDR circuits between all input ports requires the use of analog multiplexer circuits, as the signals presented to the analog multiplexer after equalization are of low signal strength and have insufficient signal-to-noise ratio to allow handling by digital multiplexer circuitry.

### CROSS-REFERENCE TO RELATED APPLICATION

This application claims the benefit of U.S. Provisional Patent Application No. 60/859,639 filed Nov. 16, 2006.

### BACKGROUND OF THE INVENTION

1. Field of the Invention

The present invention relates to HDMI video receivers, and specifically to the realization of a high speed HDMI receiver with reduced die size and power consumption.

2. Prior Art

High-Definition Multimedia Interface (HDMI) is the industry-supported, uncompressed, all-digital audio/video interface. By delivering crystal-clear, all-digital audio and video via a single cable, HDMI dramatically simplifies cabling and helps provide consumers with the highest quality home theater experience. HDMI provides an interface between any audio/video source, such as a set-top box, DVD player, or A/V receiver and an audio and/or video monitor, such as a digital television (DTV), over a single cable. A typical input port with HDMI interface carries signals on four channels, three video data channels and one clock channel.

Typical industry practice in this field, for receiver input block, is to use digital multiplexing of input line data after the high-speed input has been recovered and de-serialized to digital format. This requires that each input channel of the port have an equalization circuit for both the data and clock channels followed by a clock/data recovery (CDR) circuit which includes a deserializer, for each data channel of the port. This necessitates one equalization block, with four equalization circuits and one CDR block, with three CDRs, per port. The output of this CDR circuit is a ten-bit parallel digital data stream. The digital multiplexer block uses a set of multiplexer circuits equal to the total number of digital signal channels presented to it, typically from the three CDRs each having ten parallel signal channels, making a total of a thirty channel output. Each multiplexer circuit, has inputs equal to the number of data ports ‘n’ and is used for selection of one channel out of the ‘n’ similar channels from the plurality of ports. A HDMI port contains four channels, three data channels, channel 1 through 3, and one clock channel 0. After data recovery and de-serialization in the CDR block associated with each port, thirty parallel output channels of digital signal per port is presented to the digital multiplexer block (digital MUX). The digital MUX therefore requires thirty digital multiplexing circuits each with inputs equal to the number of ports. As an example, all of channels ‘1’ from every CDR block are provided as an input to a single multiplexer circuit and there will be thirty such ‘n’ input multiplexer circuits in the digital MUX.

FIG. 1A is a block diagram of a prior art input stage 100 of a typical HDMI video receiver with 4 ports. FIG. 1B is an expanded block diagram of one port 110 of FIG. 1A. Even though only four ports are shown in FIG. 1A, the number of input ports can vary and can be any number ‘n’. Each HDMI input port 110, 120, 130 and 140 shown has four input channels each, that use transition minimized differential signaling (TDMS) link protocol for transfer of data or clock. Of these four channels, as shown as example in FIG. 1B for the port 110, three channels, 112, 113 and 114 are video channels and the fourth channel 111 is a clock channel. The clock channel 111 has a clock running at a frequency of 1/10^{th} of the frequency of the incoming data. The incoming signals into the receiver from each port are equalized in the equalizer block 150 of FIG. 1A, having a set of four equalizer circuits, 150-0, to 150-3 as shown in FIG. 1B, one for each channel of the input port. The equalized signal is then passed to the CDR block 160 of FIG. 1A, each CDR block has three CDR circuits 160-1 to 160-3 shown in FIG. 1A, one for each data channel of equalized signal from the equalizer block. Each CDR circuit recovers the data from one data channel of input using the clock to recover and synchronize the data and converts the serial stream into digital output on a 10-bit parallel bus. The output of each CDR circuit is the reconstructed, parallel digital signal stream. The output of the tree CDRs 160-1 to 160-3 are combined onto a 30 bit wide output bus 165-Px. There is hence four such output buses, 165-P1 to 165-P4, one for each input port. These output buses 165-P1 to 165-P4 are connected to the digital MUX 170. Each of the similar or corresponding parallel data channels from multiple HDMI input ports 110 to 140 is multiplexed using digital MUX 170. The digital MUX has a set of digital multiplexer circuits 170-0 to 170-29 equal to the number of channels per input bus width into the digital MUX. Each of the above referred digital multiplexer circuits having inputs equal to the number of input ports. The digital MUX 170 can select the 30 parallel channels from the CDR block associated with any one of the four ports to be passed through to the next stage on output bus 190. The selection is based on the select signals 180 input into the multiplexer block. The output 190 of this multiplexer block 170 is the 30 bit wide parallel data from the selected input port for further processing. This structure requires an equalizer circuit per input channel and a CDR circuit for every data channel of every input port. That is, for the example, the number of input ports times 4 equalizers and input port times 3 CDRs, resulting in 16 equalizers and 12 CDR circuits in a typical four port HDMI input stage of the exemplary integrated circuit.

The digital MUX also requires thirty, four-input multiplexer circuits to enable the selection of one of four input ports of the above example. If the input port number is increased, the number of inputs to the multiplexer circuit will increase proportionately while the number of the multiplexer circuits in the multiplexer block will remain at thirty.

The CDR circuit used takes up valuable silicon area and dissipates operational power. As the speed, i.e., as the frequency of operation of the system increases, the power increases in proportion to the increased frequency. It is therefore advantageous to reduce the number of CDR blocks to improve silicon area utilization. It is further advantageous to reduce the number of CDR blocks to reduce power drain, especially as the input rates move to 2.5 Gbits/sec and beyond.

### BRIEF DESCRIPTION OF THE DRAWINGS

FIG. 1A is the block diagram of prior art HDMI receiver input block with four ports.

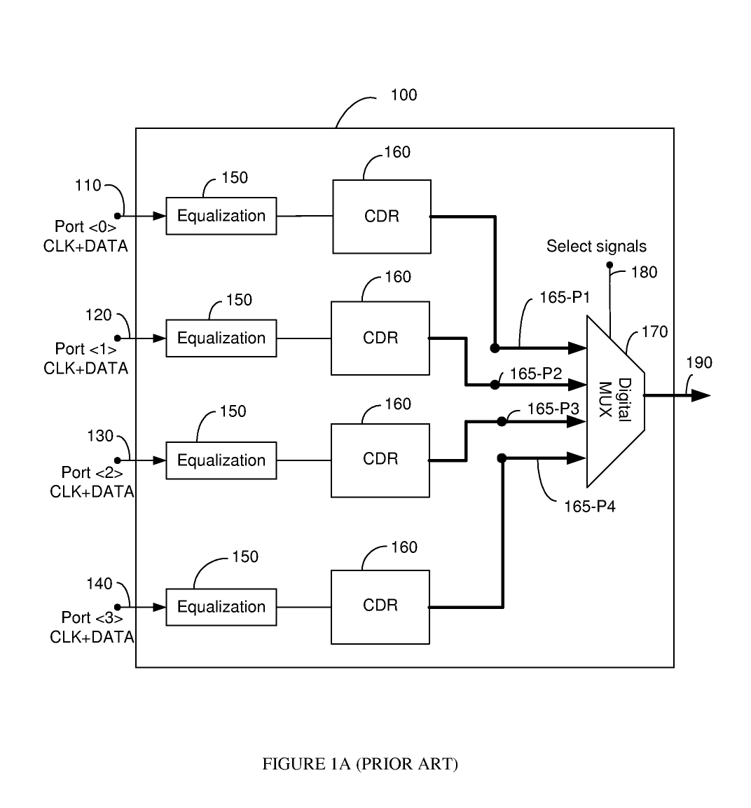

FIG. 1B is the expanded block diagram of a port of the HDMI receiver input block in FIG. 1A.

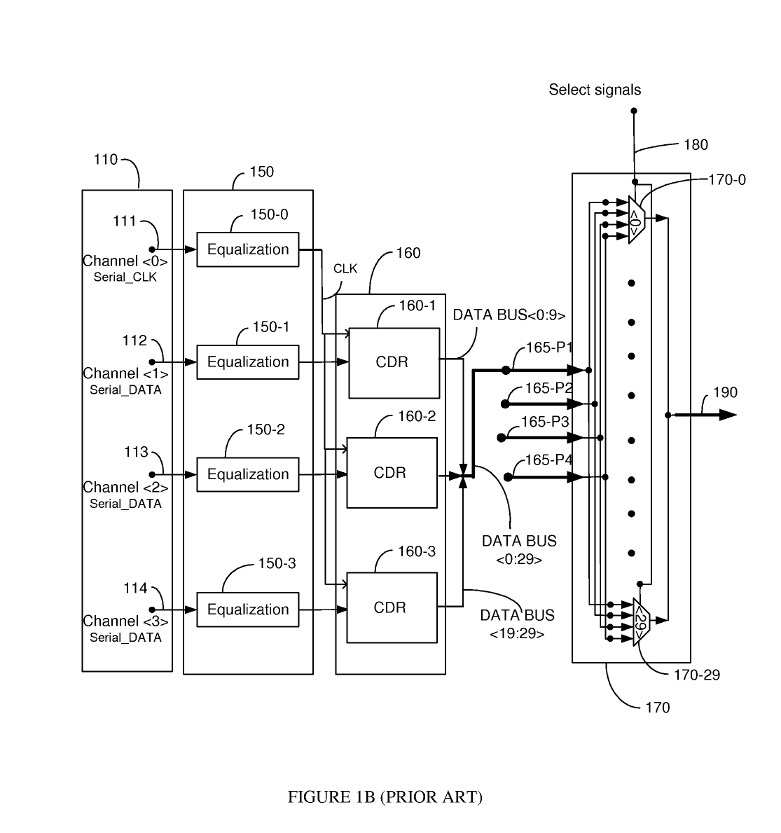

FIG. 2A is the block diagram of the current HDMI receiver input block with four ports.

FIG. 2B is the expanded block diagram of one port of the disclosed HDMI receiver input block in FIG. 2A.

FIG. 3 is the circuit diagram of a channel of the analog multiplexer circuit for ‘4’ input ports.

### DETAILED DESCRIPTION OF THE PREFERRED EMBODIMENTS

Described herein are analog multiplexers or Analog Multiplexer Blocks, (analog MUX) in High Definition Multimedia Interface (HDMI) receiver input sections. The purpose of the analog multiplexer is to reduce the die size and power consumption by selecting the input signal from one port out of a set of input ports right after the equalization, and therefore use only one CDR block comprising CDRs circuits equal to the number of data channels of the input port for recovery and deserialization of data. This sharing of one block of CDRs between all input ports requires the use of analog MUX circuits, as the signals presented to the multiplexer after equalization are of low signal strength and have insufficient signal to noise ratio to allow handling Therefore, the present invention disclosure relates to the use of a low noise analog MUX to pre-select the signals from an input port out of multiple available input ports of a HDMI receiver prior for clock and data recovery. A single block of CDR circuits, equal in number to the number of data channels per port, is all that is necessary in the input block for clock and data recovery. In addition, since the serial data from the equalizer circuits are multiplexed, including the clock signal, only four analog MUX circuits are needed for the multiplexer block. Each of the analog MUX circuits will have as many inputs as the number of input ports.

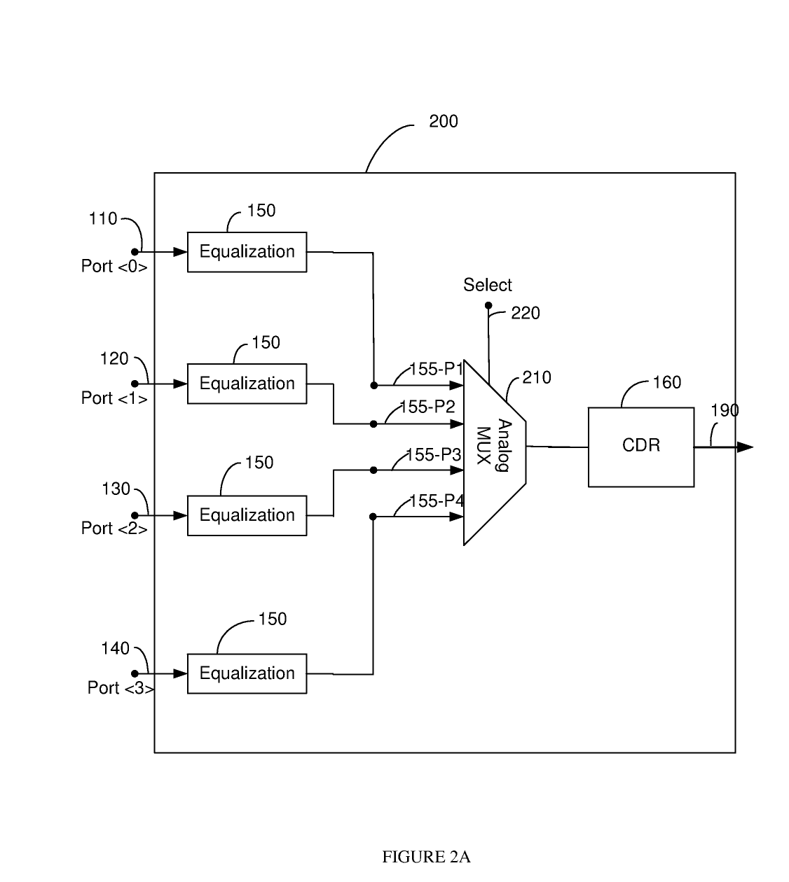

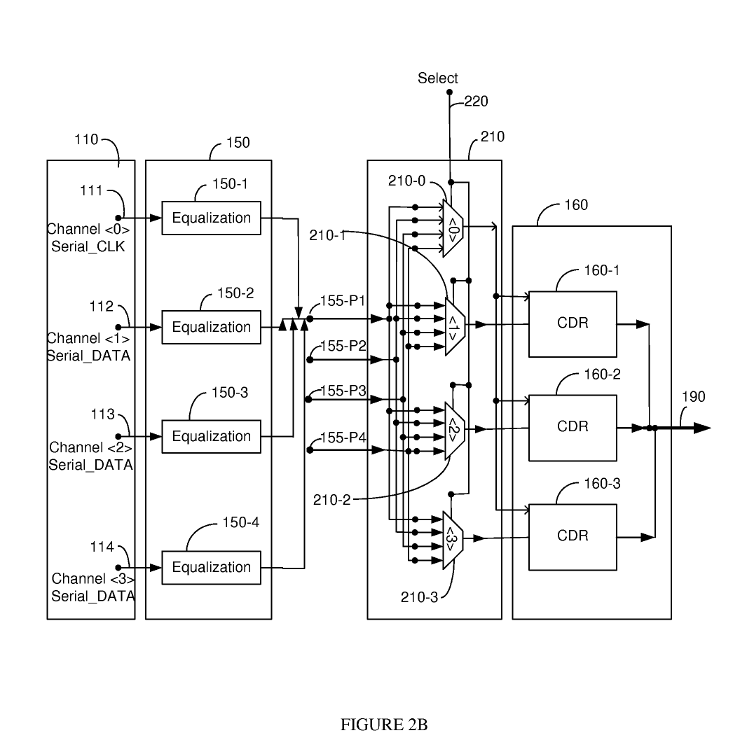

FIG. 2A is a block diagram 200 of a typical exemplary and non-limiting 4-port input stage implementation of the HDMI video receiver as per the present disclosure, and FIG. 2B is an expanded block diagram of one channel of the disclosure shown in FIG. 2A. The four HDMI ports 110 to 140 each have four channels, one carrying clock and three carrying data. FIG. 2B shows the four input channels of port 110, 111 being the clock channel and 112 to 114 being the three data channels. The equalizer block 150 associated with each port has a set of four equalizer circuits, 150-0 to 150-3 as shown in FIG. 2A, one for each channel of the port. The output of the equalizer block 150 is sent to a low noise analog MUX, 210. There is a set of four analog multiplexer circuits, 210-0 to 210-3, in the analog MUX. Each circuit is a four-input multiplexer circuit, to multiplex similar or corresponding channels from the four input ports. For example Channel ‘1’s from all the ports, or channel ‘2’s from all the ports or clock channels from all the four input ports. The selection signal 220 selects one set of signals, exemplified by 155-P1 corresponding to input port 110 in FIG. 2B out of the four input signals 155-P1 to 155-P4 presented to the analog MUX 210 from the four input port 110 to 140 after equalization. The selected signals 155-P1 from port 110 are passed through the analog MUX 210 and sent to the CDR block 160. The CDR block 160 is comprised of three CDR circuits 160-1 through 160-3, one for each selected data channel. The three data channels in FIG. 2B, selected by the analog multiplexer circuits 210-1 to 210-3, are input into the three CDR circuits 160-1 to 160-3 of the CDR block 160. The selected clock input from multiplexer circuit 210-0 is supplied to the three CDR circuits to synchronize and de-serialize each input data stream. Each input channel is handled by a respective CDR circuit. The analog MUX 210 is used in this disclosure to select the input port of choice prior to the recovery of clock and data in the CDR block 160. The three CDR circuits are therefore shared between all the input ports of the system, with a CDR per port data channel. There is only a need for a single CDR block comprising three CDR circuits, for the disclosed HDMI example, irrespective of the number of HDMI ports at the input. This pre-selection of the port using the low noise analog MUX 210, prior to the clock and data recovery, reduces the number of CDR circuits used. For example, for the equivalent exemplary prior art four-input port receiver using sixteen CDR circuits, only four CDR circuits can be used in accordance with the principles of the current invention.

Even though the exemplary and non-limiting example discussed above of FIG. 2A was for a four-input port, the number of ports can be any number ‘n’. In a typical implementation of HDMI inputs with four channel/input ports and ‘n’ input ports, the number of CDR blocks is reduced to a single block of three CDR circuits. When this is compared to a CDR block of three circuits for each one of the ‘n’ input ports used in the prior art receivers, the savings are self evident, going from 3 times ‘n’ to 3 CDR circuits on-chip. This invention therefore reduces the number of CDR circuits used from a block of three circuits for every input port to one block of three circuits for all incoming ports. This in turn leads to reduction in die size, reduction in power consumption and lower cost.

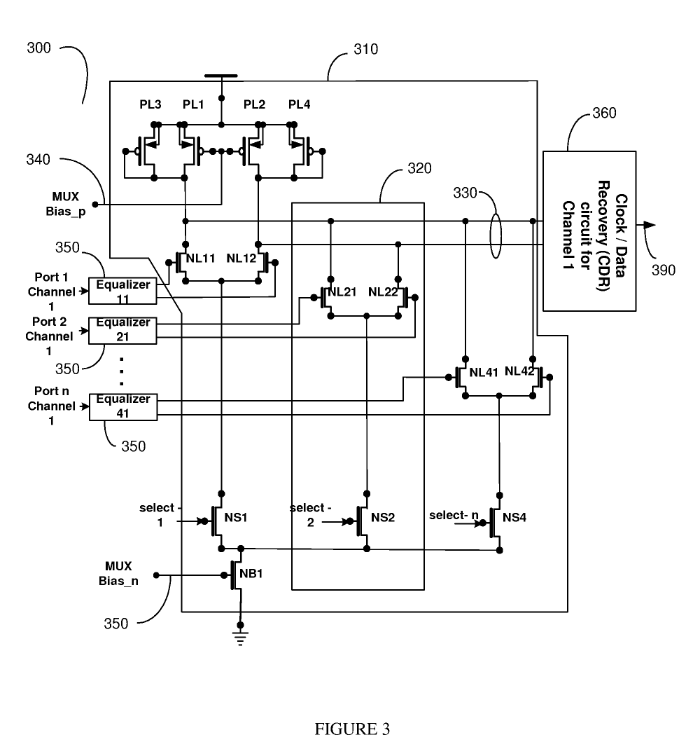

The reason for the use of analog multiplexers for the HDMI receiver of this disclosure is that the signal strength of the input is too small prior to the CDR block CDR for the use of a digital multiplexer. The low signal swings at the input of a digital circuit designed for rail-to-rail operation can degrade the input signal-to-noise ratio and therefore make the signal non-recoverable. Therefore, in accordance with the principles of the disclosed invention, sensitive analog multiplexers, for example analog multiplexer circuits 210-0 to 210-3, are used prior to data and clock recovery. A typical circuit implementation is shown in FIG. 3, which provides signal amplification with low noise addition.

The use of the analog MUX after the equalizer circuits reduces the need for the large number of digital multiplexer circuits to four analog multiplexer circuits in the disclosed invention. This is due to the fact that the three serial input streams of data and one clock from the four selected input channels only need to be multiplexed. Thus the four channels can be multiplexed with only four analog multiplexer circuits. This reduces the number of multiplexer circuits from thirty digital multiplexer circuits, handling the parallel data after the recovery and de-serialization in the prior art implementation, to four analog multiplexer circuits in the present invention. This again leads to reduction in silicon area used by the input receiver stage of the HDMI Video receiver.

The exemplary multiplexer circuit disclosed herein is a high speed, 2.5 Gb/s low noise analog multiplexer circuit shown in FIG. 3. The use of this multiplexer circuit provides the necessary high-speed operational capability for the input receiver section to meet the high speed HDMI serial specification.

FIG. 3 shows the circuit for one channel 300 of the input section 200 of FIG. 2A with four input ports. The equalization circuits 350 shown are one of four equalization circuits in each block 150 of FIG. 2A, each equalization circuit shown handling a similar channel of input from the port. The single analog multiplexer circuit 310 shown is one of the four circuits included in the multiplexer block 210 of FIG. 2A. It is composed of multiple repeated cells 320, equal to the number of input ports, forming part of a differential amplifier with the P-channel devices PL1 to PL4. The cells are selected by the select signal applied to one of the devices NS1 to NS4. If port 2 is the input is to be selected, the select signal is applied to NS2. This turns on the differential amplifier consisting of the P channel devices PL1 to PL4 and the N-channel devices in the selected cell consisting of NL21 and NL22. This differential amplifier amplifies and passes through the signal from the selected input port to the output 330 of the multiplexer and to the single CDR circuit 360 that is one of the three CDR circuits 160-1 to 160-3 of FIG. 2B, handling that channel.

The amplifier NL21 and NL22 within each cell 320 increases the signal to noise ratio so that the output signal of the MUX will not lose signal quality and the clock and data recovery will be easier by the subsequent CDR stage. being provided for the P channel devices through input 340, and the second for N-channel transistors through input 350 applied to the gate of the biasing driver NB1 for the N-channel cells.

Even though the disclosure is directed toward HDMI integrated circuit implementations, it will have applications in other areas and other fields of electronic circuits including, but not limited to, new video receiver technologies as will be well known to practitioners of the art.

Some of the unique features of the present invention include:

1. Use of a high-speed 2.5 Gbps analog multiplexer instead of the digital multiplexer in the circuit to achieve the HDMI serial specifications.

2. Moving the multiplexer to a position soon after equalization circuits enable the port selection early and allow a single set of CDRs for all data ports, i.e., one CDR circuit per port-data_channel to be used, instead of one CDR circuit per data channel for every input port of the receiver.

3. Using the single CDR per port-data_channel with analog multiplexer reduces the chip area by elimination of the multiple digital CDRs of the prior art and hence reduce the cost of the chip.

4. The single CDR per port-data_channel is effective in cutting down the power usage as the frequencies increase.

5. Use of the single CDR per port-data_channel reduce the power consumption of the chip with associated reduction in the cooling cost and package cost.

6. It is possible to use this circuit in other areas of electronic engineering circuitry to achieve similar reduction in power, chip area and cost of the integrated circuit.

While an exemplary preferred embodiment of the present invention has been disclosed and described herein for purposes of illustration and not for purposes of limitation, it will be understood by those skilled in the art that various changes in form and detail may be made therein without departing from the spirit and scope of the invention.

What is claimed is:

1. An input block of a receiver for selecting one input port out of a plurality of input ports, each port having a plurality of input channels, comprising:
a plurality of equalizers, each coupled to a respective one of the plurality of input channels of the plurality of input ports;
a plurality of low-noise analog multiplexers, each having inputs coupled to respective ones of the plurality of equalizers that are coupled to respective channels of each of the input ports;
a plurality of clock and data recovery (CDR) circuits, each coupled to an output of a respective low-noise analog multiplexer;
a control coupled to said low-noise analog multiplexers for selecting a respective one of the plurality of inputs of said low-noise analog multiplexers to be output to the respective clock and data recovery circuit.

2. The input block of claim 1, wherein said low-noise analog multiplexers include amplification to prevent signal to noise ratio degradation of a selected input signal to said low-noise analog multiplexers.

3. The input block of claim 1, wherein said low-noise analog multiplexers are high speed analog multiplexers, enabled to achieve high-definition multimedia interface transmission rates.

4. The input block of claim 1, wherein the selection of one input port prior to clock and data recovery reduces the need for clock and data recovery circuits to one per port data-channel shared between all ports.

5. The input block of claim 1, wherein each port of said plurality of input ports further comprises a plurality of data channels and a clock channel.

6. The input block of claim 1, wherein the number of said plurality of equalizers is equal to the total number of data channels and clock channels from all the said input ports.

7. The input block of claim 1, wherein the number of said plurality of low-noise analog multiplexers is equal to the number of data channels and clock channel of each of said input ports.

8. The input block of claim 7, wherein each of said low-noise analog multiplexers has a number of inputs equal to the number of the plurality of said input ports.

9. The input block of claim 1, wherein the input block comprises an input stage of a high-definition multimedia interface receiver integrated circuit.

10. A method of selecting inputs from one input port out of multiple input ports comprising:
using high speed and low noise analog multiplexer circuits, after equalization but prior to clock and data recovery, in a high-definition multimedia interface (HDMI) video receiver integrated circuit;
whereby a single set of clock and data recovery circuits can be shared between all the input ports.

11. A method for selecting input signals received on multiple channels of one of a plurality of input ports comprising:
a) equalizing the received input signals;
b) selecting a signal path of low-noise analog multiplexers corresponding to each of the input signals of a selected input port; and,
c) performing a recovery on the output of said low noise analog multiplexers that comprises at least one of: clock recovery, data recovery.

12. The method of claim 11, wherein said performing a recovery further comprises:
sharing of clock and data recovery circuits between said plurality of input ports.

13. The method of claim 12, where said sharing of the clock and data recovery circuits further comprises;
reducing the power dissipation of an integrated circuit input stage.

14. The method of claim 11, wherein said low-noise analog multiplexer enables an integrated circuit to achieve serial transmission up to 2.5 Gb/second.

15. The method of claim 11, wherein the method is practiced in an input stage of a high-definition multimedia interface receiver integrated circuit.

16. An input block of a receiver for selecting one input port out of a plurality of input ports, each input port having a plurality of input channels, including one clock channel and a plurality of data channels, comprising:
a plurality of equalizers, each coupled to a respective one the plurality of input channels of the plurality of input ports;
a plurality of low-noise analog multiplexers equal in number to the number of input channels per port, the inputs of each being coupled to an equalizer output for a respective channel of each of the input ports;
a plurality of clock and data recovery (CDR) circuits equal in number to the number of channels in each input port;
the plurality of low-noise analog multiplexers being responsive to a select signal for coupling the outputs of equalizers for a selected port to the clock and data recovery circuits.

17. The input block of claim 16, wherein said low-noise analog multiplexers comprise high speed analog multiplexers to achieve high-definition multimedia interface transmission rates.

18. The input block of claim 16, wherein the input block comprises an input stage of a high-definition multimedia interface receiver integrated circuit.

19. A method for selecting input signals received on multiple channels of any of a plurality of input ports comprising:
a) equalizing the received input signals;
b) selecting a signal path through low-noise analog multiplexers corresponding to input signals of a selected port; and,
c) performing a recovery on the output of said low noise analog multiplexers that comprises at least one of: clock recovery, data recovery.

20. The method of claim 19, wherein said performing a recovery further comprises:
sharing of clock and data recovery circuits between said plurality of input ports.

21. The method of claim 19, wherein said low-noise analog multiplexers enable an integrated circuit to achieve serial transmission up to 2.5 Gb/second.

22. The method of claim 19, wherein the method is practiced in an input stage of a high-definition multimedia interface receiver integrated circuit.
